(19) United States
(12) Patent Application Publication
(10) Pub. No.: US 2024/0387169 A1
(43) Pub. Date: Nov. 21, 2024

(54) METHOD FOR FORMING SEMICONDUCTOR DEVICE HAVING CRYSTALLINE SEMICONDUCTOR FILM

(71) Applicant: Taiwan Semiconductor Manufacturing Company, Ltd., Hsinchu (TW)

(72) Inventors: Yen-Chieh Huang, Changhua County (TW); I-Cheng Chang, Hsinchu City (TW); Kai-Wen Cheng, Taichung City (TW); Yu-Ming Lin, Hsinchu City (TW); Chung-Te Lin, Tainan City (TW)

(73) Assignee: Taiwan Semiconductor Manufacturing Company, Ltd., Hsinchu (TW)

(21) Appl. No.: 18/318,726

(22) Filed: May 17, 2023

(51) Int. Cl. H01L 21/02

(52) U.S. Cl. CPC H01L 21/02472; H01L 21/02205; H01L 21/02323; H01L 21/0234; H01L 21/02554

(57) ABSTRACT

A method for forming a semiconductor device is provided. The method includes providing a substrate; supplying a first precursor including a first metal element; forming a first layer of a first metal oxide material containing the first metal element over the substrate, wherein the first metal element includes a Group 13 element; supplying a second precursor including a second metal element and a third metal element; forming a second layer of a second metal oxide material that contains the second metal element and the third metal element directly on the first layer to form a crystalline metal oxide semiconductor film containing the first, second and third metal elements, wherein the second metal element and the third metal element are different and each being independently selected from Group 12 elements, Group 13 elements, and Group 15 elements, and the second and third metal elements contained in the second metal oxide material are aligned with the first metal element contained in the first metal oxide material along a vertical crystalline axis direction to form the crystalline metal oxide semiconductor film; forming a source terminal and a drain terminal respectively on and in contact with the crystalline metal oxide semiconductor film; forming a dielectric layer over the substrate; and forming a gate layer on the dielectric layer.

### BACKGROUND

With advances in semiconductor technology, there has been increasing demand for faster devices with lower power consumption. In order to provide transistors with higher channel mobility and lower off state current, a channel material with improved properties is highly desirable.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a thin-film deposition system in accordance with some embodiments of the disclosure.

FIG. 2 is a flow diagram of a method for forming a crystalline metal oxide semiconductor film in accordance with some embodiments of the disclosure.

FIG. 3 is a schematic cross-sectional view showing a composite structure of a crystalline metal oxide semiconductor film in accordance with some embodiments of the disclosure.

FIG. 4 is a flow diagram of steps for forming a first metal oxide layer in Process 220 of FIG. 2 in accordance with some embodiments of the disclosure.

FIG. 5 is a flow diagram of steps for forming a second metal oxide layer in Process 240 of FIG. 2 in accordance with some embodiments of the disclosure.

FIG. 6 is a schematic view of a thin-film deposition system in accordance with some embodiments of the disclosure.

FIG. 7 is a schematic view of a thin-film deposition system in accordance with some embodiments of the disclosure.

FIG. 8 is a schematic view of a thin-film deposition system in accordance with some embodiments of the disclosure.

FIG. 9 is a flow diagram of a method for forming a crystalline metal oxide semiconductor film in accordance with some embodiments of the disclosure.

FIG. 10 is a schematic cross-sectional view of an exemplary structure of a top-gate thin film transistor (TFT) in accordance with some embodiments of the disclosure.

FIG. 11 is a schematic cross-sectional view of an exemplary structure of a bottom-gate TFT in accordance with some embodiments of the disclosure.

FIG. 12 is a schematic cross-sectional view of an exemplary structure of a double gate TFT in accordance with some embodiments of the disclosure.

FIG. 13 is a schematic cross-sectional view of an exemplary structure of a top-gate ferroelectric field effect transistor (FeFET) in accordance with some embodiments of the disclosure.

FIG. 14 is a schematic cross-sectional view of an exemplary structure of a bottom-gate FeFET in accordance with some embodiments of the disclosure.

FIG. 15 is a schematic cross-sectional view of an exemplary structure of a double gate FeFET in accordance with some embodiments of the disclosure.

FIG. 16 is a schematic cross-sectional view of an exemplary structure of a vertical TFT in accordance with some embodiments of the disclosure.

FIG. 17 is a schematic cross-sectional view of an exemplary structure of a vertical FeFET in accordance with some embodiments of the disclosure.

FIG. 18 is a schematic cross-sectional view of a one-transistor-one-capacitor (1T1C) ferroelectric random access memory (FeRAM) cell in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

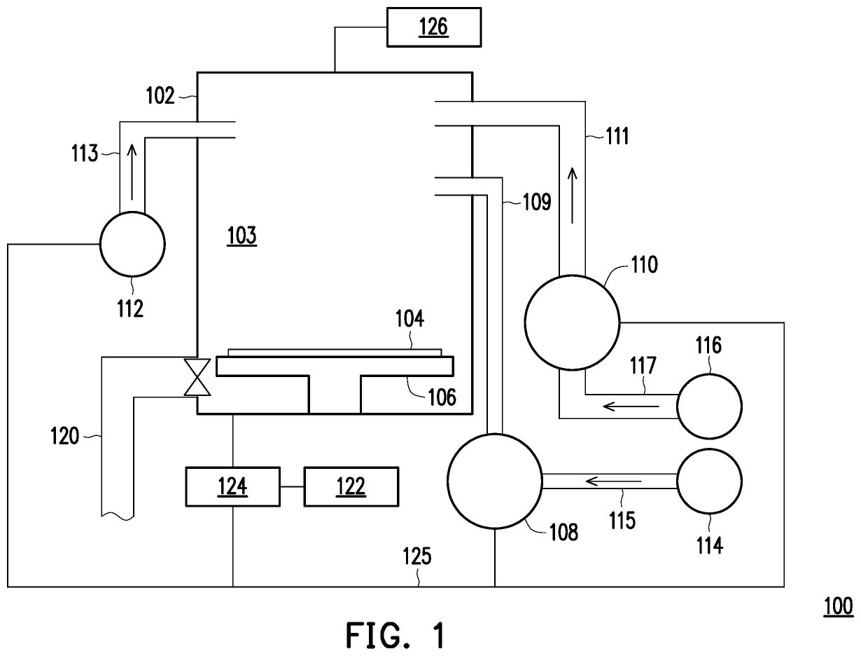

FIG. 1 is a schematic view of a thin-film deposition system 100 in accordance with some embodiments of the disclosure. The thin-film deposition system 100 includes a deposition chamber 102 including an inner space 103. A support 106 is positioned within the inner space 103 and is configured to support a substrate 104 during the deposition process for a thin film on the substrate 104. The thin-film deposition system 100 includes a control system 124 that dynamically adjusts deposition parameters for forming thin films.

In some embodiments, the thin-film deposition system 100 is a deposition system for forming thin films. In some embodiments, the deposition system 100 is an atomic layer deposition (ALD) system for performing ALD processes. For example, a metal oxide layer, such as an indium oxide layer or a gallium zinc oxide layer, may be formed on the substrate 104 by performing one or more ALD processes. However, other types of thin-film deposition systems may be utilized without departing from the scopes of the present disclosure.

In one embodiment, the thin-film deposition system 100 includes a first reactant source 108, a second reactant source 110 and a third reactant source 112. In one embodiment, the first, second and third reactants are reactants used for depositing a metal oxide semiconductor film on the substrate 104. The first reactant source 108 supplies a first reactant into the inner space 103 and is coupled to the deposition chamber 102 by a feeding line 109. The second reactant source 110 supplies a second reactant into the inner space 103 and is coupled to the deposition chamber 102 by a feeding line 111. The third reactant source 112 supplies a third reactant into the inner space 103 and is coupled to the deposition chamber 102 by a feeding line 113.

In one embodiment, the first and second reactant sources 108, 110 may provide the reactants in a power form or as particles. In some embodiments, the thin-film deposition system 100 further includes a first purge tank 114 supplying a first carrier fluid and a second purge tank 116 supplying a second carrier fluid. The first purge tank 114 is coupled with the first reactant source 108 by a purge line 115. The second purge tank 116 is coupled with the second reactant source 110 by a purge line 117. When the first reactant source 108 is “on” (supplying the first reactant) and the first purge tank 114 is “on” (supplying the first carrier fluid), the first carrier fluid carries the first reactant into the inner space 103 of the chamber 102. When the first reactant source 108 is “off” (stop supplying the first reactant) and the first purge tank 114 is “on” (supplying the first carrier fluid), the first carrier fluid functions as the purge gas to purge (flush out) the first reactant out of the inner space 103 of the chamber 102. By switching “on” and “off” the reactant source and the purge tanks respectively, the supply and/or the discharge of the reactants and carrier gases may be controlled. The carrier fluid is selected to any suitable fluid or gas inactive with the substrate 104, the thin-film layer deposited on the substrate 104, the first and second reactants, and byproducts of this first or second reactant. Accordingly, the carrier fluid may be an inert gas including, but not limited to, argon (Ar) gas or nitrogen (N₂) gas.

While FIG. 1 illustrates a first reactant source 108 and a second reactant source 110, in practice the thin-film deposition system 100 may include other numbers of reactant sources. For example, the thin-film deposition system 100 may include only a single reactant source or more than two reactant sources. Accordingly, the thin-film deposition system 100 may include a different number than two reactant sources without departing from the scope of the present disclosure.

In one embodiment, the thin-film deposition system 100 includes a discharge pipe 120 communicatively coupled to the inner space 103 of the deposition chamber 102. Exhaust products from the thin-film deposition process flow out of the inner space 103 via the discharge pipe 120. The exhaust products may include unreacted portions of the first and second reactants, byproducts of the first and second reactants, carrier fluids used to carry the first and second reactants or purge the inner space 103, or other fluids or materials.

In one embodiment, the thin-film deposition system 100 includes a control system 124. The control system 124 is coupled to the byproduct sensor 122. The control system 124 receives the sensor signals from the byproduct sensor 122. The sensor signals from the byproduct sensor 122 are indicative of the concentration of byproducts of one or both of the first and second reactants in the exhaust fluid. The control system 124 analyzes the sensor signals and determine a flow rate or concentration of one or both of the first and second reactant sources 108, 110 during particular stages of the deposition process. The control system 124 also determines a remaining level of the first reactant in the first reactant source 108 and/or of the second reactant in the second reactant source 110.

In one embodiment, the thin-film deposition system 100 includes one or more valves, pumps, or other flow control mechanisms for controlling the flow rate of the first reactant from the first reactant source 108. These flow control mechanisms may be part of the reactant source 108 or may be separate from the reactant source 108. The control system 124 may be communicatively coupled to these flow control mechanisms or to systems that control these flow control mechanisms. The control system 124 controls the flowrate of the first reactant by controlling these mechanisms. The control system 100 may include valves, pumps, or other flow control mechanisms that control the flow of the second reactant from the second reactant source 110 in the same manner as described above in reference to the first reactant and the first reactant source 108. In some embodiments, the thin-film deposition system 100 further includes a RF generator 126 for generating plasma.

In some embodiments, the control system 124 includes one or more computer readable memories. For example, the one or more memories store software instructions for analyzing sensor signals from the byproduct sensor 122 and for controlling various aspects of the thin-film deposition system 100 based on the sensor signals. The control system 124 may include one or more processors configured to execute the software instructions. The control system 124 may include communication resources that enable communication with the byproduct sensor 122 and other components of the thin-film deposition system 100.

In one embodiment, the control system 124 is communicatively coupled to the first, second and third reactant sources 108, 110 and 112 and purge tanks 114, 116 via one or more communication channels 125. The control system 124 sends signals to the first, second and third reactant sources 108, 110 and 112 and purge tanks 114, 116 via the communication channels 125. The control system 124 controls functionality of the first, second and third reactant sources 108, 110 and 112 and purge tanks 114, 116 responsive, in part, to the sensor signals from the byproduct sensor 122.

The thin-film deposition system 100 utilizes the control system 124 to dynamically adjust process conditions to ensure that deposition processes result in thin films having parameters or characteristics that fall within target parameters or characteristics. The control system 124 is connected to processing equipment associated with the thin-film deposition system 100. The processing equipment may include components shown in FIG. 1 and components not shown in FIG. 1. The control system 124 controls the flow rate of material from the reactant sources 108, 110 and 112, the temperature of materials supplied by the reactant sources 108, 110 and 112, the pressure of fluids provided by the reactant sources 108, 110 and 112, the flow rate of material from purge tanks 114 and 116, the duration of flow of materials from the reactant sources 108, 110 and 112 and the purge tanks 114 and 116, the reaction temperature within the deposition chamber 102, the pressure within the deposition chamber 102, the humidity within the deposition chamber 102, and other aspects of the thin-film deposition process. The control system 124 controls these process parameters so that the thin-film deposition process results in a thin-film having target parameters such as a target thickness, a target composition, a target crystal orientation, etc.

In one embodiment, the control system 124 determines how much of the first reactant remains in the first reactant source 108 based on the sensor signals from the byproduct sensor 122. The control system 124 may analyze the sensor signals to determine that the first reactant source 108 is empty or is nearly empty. The control system 124 provides an indication to technicians or other personnel indicating that the first reactant source 108 is empty or nearly empty and that the first reactant source 108 should be refilled or replaced. These indications may be displayed on a display and transmitted via email, instant message or other communication platforms that enable technicians or other experts or systems to understand that one, two or all of the first, second and third reactant sources 108, 110 and 112 are empty or nearly empty.

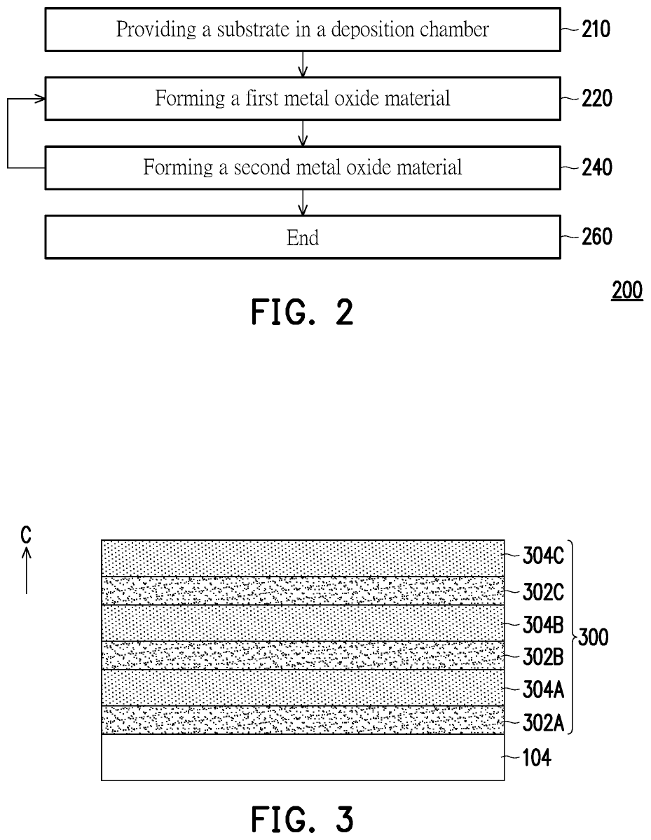

FIG. 2 is a flow diagram of a method 200 for forming a crystalline metal oxide semiconductor film in accordance with some embodiments of the disclosure. FIG. 3 is a schematic cross-sectional view showing a composite structure of a crystalline metal oxide semiconductor film 300 in accordance with some embodiments of the disclosure. In this embodiment, the method 200 may be carried out in the thin-film deposition system 100 as shown in FIG. 1 to form the crystalline metal oxide semiconductor film 300 as shown in FIG. 3.

Referring to FIG. 2, the method 200 includes providing a substrate 104 into the deposition chamber 102 (Process 210). In some embodiments, the substrate 104 is or includes a wafer such as a semiconductor bulk wafer or a reconstructed wafer. Referring to FIGS. 2 and 3, followed by performing Process 220, through providing a first precursor including first metal elements, a layer 302A of a first metal oxide material is formed over the substrate 104 (FIG. 3). In some embodiments, the layer 302A is a crystalline layer. In some embodiments, the first metal oxide material contains a first metal element, such as Group 13 elements (based on the definition by IUPAC). In some embodiments, the first metal oxide material includes indium oxide (InO). In one embodiment, the layer 302A is an indium oxide layer formed with a thickness ranging from about 0.1 nm to about 20 nm. Followed by performing Process 240, through providing a second precursor including a second metal element and a third metal element, a layer 304A of a second metal oxide material is formed directly on the layer 302A of the first metal oxide material. In some embodiments, the second metal oxide material contains the second metal element and third metal element, such as Group 12 elements, Group 13 elements or Group 15 elements. In some embodiments, the second metal oxide material includes gallium zinc oxide (GaZnO). In some embodiments, the first metal oxide material has a band gap smaller than that of the second metal oxide material. In one embodiment, the layer 302A is an indium oxide layer, and the layer 304A is a gallium zinc oxide layer deposited directly on the indium oxide layer 302A to form a crystalline indium gallium zinc oxide (IGZO) layer (such as a c-axis aligned crystalline IGZO layer, or nanocrystalline IGZO layer). In one embodiment, the layer 304A is a gallium zinc oxide layer formed with a thickness ranging from about 0.1 nm to about 20 nm.

Herein, c-axis aligned crystalline IGZO layer or film has a crystalline phase that has a structure in the boundary region between an amorphous structure and a crystal structure. The c-axis aligned crystalline IGZO film does not have clear grain boundaries. When seen from a direction perpendicular to the c-axis (the vertically oriented principle crystal axis), it has a layered structure in which layers formed of InO and layers formed of GaZnO are stacked alternately with interfaces seen between the alternate layers. The atoms are arranged along parallel planes or aligned along the c-axis direction as in the crystalline structure.

In some embodiments, Processes 220-240 are performed as a cycle, and such cycle may be repeated one or more times to form multiple layers of the first metal oxide material and multiple layers of the second metal oxide material that are stacked alternately. In some embodiments, following the formation of the layers 302A, 304A, the cycle of Processes 220-240 is repeated to form a layer 302B of the first metal oxide material on the layer 304A and a layer 304B of the second metal oxide material directly on the layer 302B, and another cycle of Processes 220-240 is repeated to form a layer 302C of the first metal oxide material on the layer 304B and a layer 304C of the second metal oxide material directly on the layer 302C, to form the crystalline metal oxide semiconductor film 300. The numbers of the cycles and the layers of the first metal oxide material and the second metal oxide material may vary depending on the desired thickness of the crystalline metal oxide semiconductor film 300. Next, once the desired composite structure or the desired thickness of the crystalline metal oxide semiconductor film 300 is obtained, the method 200 may be terminated (Process 260).

Using the formation of the crystalline IGZO layer as an example, the process cycle includes firstly forming an InO layer and then forming a GaZnO layer directly on the InO layer so as to form the crystalline IGZO layer. The formation energy needed for forming the crystalline IGZO layer is reduced and the crystallization temperature of the crystalline IGZO layer is lower (e.g. less than 300° C. or less than 200° C.), compared with supplying all the reactants at once for forming amorphous IGZO layer. As the GaZnO layer containing gallium and zinc is formed directly on the InO layer and is in contact with the InO layer, an intermediate reaction may occur between the underlying InO layer and the later formed GaZnO layer, which assists the crystallization and lowers the required energy for forming the crystalline IGZO layer. Possible intermediate reaction includes electron transfers between the underlying InO layer and the later formed GaZnO layer, weakening or breaking the bonding of metal and oxygen, local diffusion and/or rearrangement in conjunction with metal elements. As the crystalline IGZO layer, especially c-axis aligned crystalline IGZO layer, has a layered composite structure consisting of InO layers (layers containing In) and GaZnO layers (layers containing Ga and Zn) stacked alternately, the processes as described above properly provides the precursor material(s) containing gallium and zinc to form the GaZnO layer directly on the InO layer, a lower reaction temperature is used (lower than the temperature required to promote the diffusion of metal interstitials in the metal oxide material) as gallium and zinc are co-supplied to form the GaZnO layer and less rearrangement is needed. By providing the precursor material(s) containing gallium atoms and zinc atoms, the gallium atoms and zinc atoms directly contact the surface of the InO layer and align with the atoms of the InO layer in a self-aligned way along the vertical crystalline axis (c-axis) direction, so that the c-axis aligned crystalline IGZO layer is formed at a lower temperature or formed with a lower thermal budget.

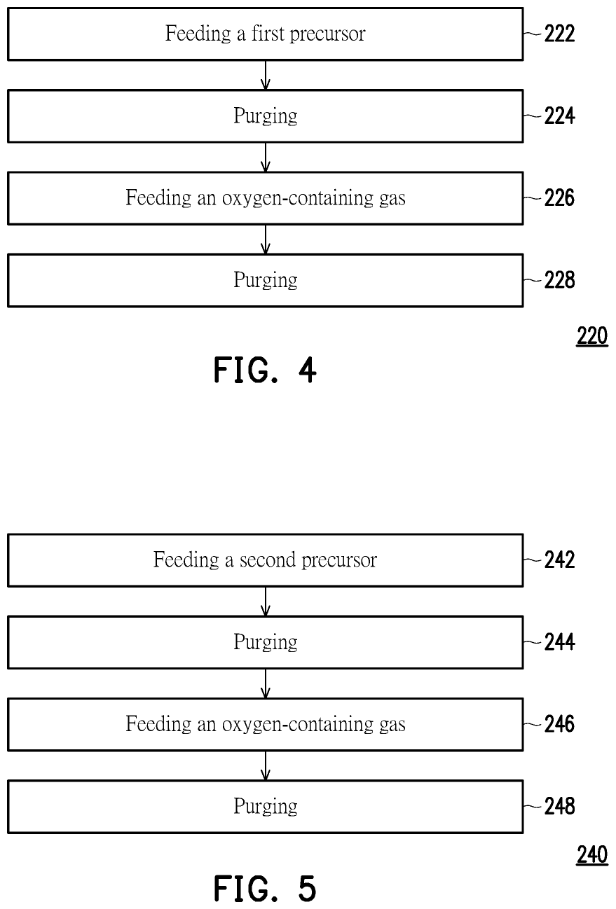

FIG. 4 is a flow diagram of steps for forming the layer of the first metal oxide material in Process 220 in accordance with some embodiments of the disclosure. In some embodiments, using an atomic layer deposition (ALD) process as an example, and Process 220 includes performing sequential steps of: (i) step 222: supplying/feeding a first precursor including first elements (such as an indium precursor) from the first reactant source 108 into the inner space 103 of the deposition chamber 102; (ii) step 224: purging the inner space 103 of the deposition chamber 102 with a purge gas; and (iii) step 226: supplying/feeding an oxygen-containing gas (such as O₂, O₃ or H₂O) from the third reactant source 112 into the inner space 103 of the deposition chamber 102; and (iv) step 228: purging the inner space 103 of the deposition chamber 102 with the purge gas. In some embodiments, step 226 further includes performing an energy treatment (such as a plasma treatment or a thermal process) while supplying the oxygen-containing gas, which provides energy for assisting the formation of the layer of the first metal oxide material. In some embodiments, when step 226 further includes performing a plasma treatment, the ALD process may be a plasma-enhance ALD (PEALD) process. In some embodiments, the first precursor comprises metal particles, such as indium particles. In some embodiments, for the ALD process, the flow rate of the feeding first precursor ranges from about 100 standard cubic centimeter (sccm) to about 1,000 sccm, the pressure of the deposition chamber 102 ranges from 0.01 to 20 torr, the reaction temperature is below 300° C. and the power is below 200 watts, steps 222 and 226 are performed as feeding pulses lasted for about 0.3-10 seconds, and steps 224 and 228 are performed as purge pulses lasted for about 0.5-10 seconds. In some embodiments, for the PEALD process, the flow rate of the feeding first precursor ranges from about 100 sccm to about 5000 sccm, the pressure of the deposition chamber 102 ranges from 0.01 to 20 torr, the power is less than 200 watts, the reaction temperature is below 200° C., steps 222 and 226 are performed as feeding pulses lasted for about 0.3-10 seconds, and steps 224 and 228 are performed as purge pulses lasted for about 0.5-10 seconds.

In some embodiments, the oxygen contained in the oxygen-containing gas reacts with the first metal elements contained in the first precursor in the deposition chamber 102 to form the first metal oxide material on or over the underlying structure. In some embodiments, the first precursor, the second precursor and the oxygen-containing gas are all reactants contributing to the deposition reaction. In some embodiments, the oxygen-containing gas may be considered as part of the first precursor or the second precursor. In some embodiments, one cycle of the sequential steps 222-228 of Process 220 described above forms one layer of the first metal oxide material in the atomic level. Such cycle may be repeated for forming more than one layer.

FIG. 5 is a flow diagram of forming the layer of the second metal oxide material in Process 240 in accordance with some embodiments of the disclosure. In some embodiments, using the ALD process as an example, Process 240 includes sequential steps of: (i) step 242: supplying/feeding a second precursor including second metal elements and third metal elements from the second reactant source 110 into the inner space 103 of the deposition chamber 102 through the feeding line 111; (ii) step 244: purging the inner space 103 of the deposition chamber 102 with a purge gas; (iii) step 246: supplying/feeding an oxygen-containing gas, such as O₂, O₃ or H₂O, from the third reactant source 112 into the inner space 103 of the deposition chamber 102 through the feeding line 113; and (iv) step 248: purging the inner space 103 of the deposition chamber 102 with the purge gas. In some embodiments, step 246 further includes performing an energy treatment (such as a plasma treatment or a thermal process) while supplying the oxygen-containing gas, which provides energy for assisting the formation of the layer of the second metal oxide material. In some embodiments, when step 246 further includes performing a plasma treatment, the ALD process may be a PEALD process.

In some embodiments, for step 242, supplying the second precursor including second metal elements and third metal elements includes preparing a mixture of a second metal precursor (e.g. gallium precursor) and a third metal precursor (e.g. zinc precursor), and supplying the mixture into the chamber 102. In some embodiments, the second precursor comprises a mixture of second metal particles and third metal particles, such as a powder mixture of gallium particles and zinc particles. In some embodiments, for step 242, supplying the second precursor including second metal elements and third metal elements includes co-supplying a second metal precursor (e.g. gallium precursor) and a third metal precursor (e.g. zinc precursor) into the chamber 102, possibly from different reactant tanks. Herein, “co-supplying” means supplying at the same time and for the same duration with acceptable time differences based on the system or process in operation. For example, in step 242, gallium particles and zinc particles may be fed into the inner space 103 of the deposition chamber 102 with a very small time difference (about or less than 0.1 sec), and such time difference may be considered to be acceptable within the process window tolerance.

In some embodiments, for the ALD process, the flow rate of the feeding first precursor ranges from about 100 sccm to about 1,000 sccm, the pressure of the deposition chamber 102 ranges from 0.01 to 20 torr, and the reaction temperature is below 300° C., steps 242 and 246 are performed as feeding pulses lasted for about 0.3-10 seconds, and steps 244 and 248 are performed as purge pulses lasted for about 0.5-10 seconds. In some embodiments, for the PEALD process, the flow rate of the feeding first precursor ranges from about 100 sccm to about 500 sccm, the pressure of the deposition chamber 102 ranges from 0.01 to 20 torr, the power is less than 200 watts, and the reaction temperature is below 200° C., steps 242 and 246 are performed as feeding pulses lasted for about 0.3-10 seconds, and steps 244 and 248 are performed as purge pulses lasted for about 0.5-10 seconds. In some embodiments, the oxygen contained in the oxygen-containing gas reacts with the second metal elements and the third metal elements contained in the second precursor in the deposition chamber 102 to form the second metal oxide material. In some embodiments, one cycle of the sequential steps 242-248 described above forms at least one layer of the second metal oxide material in the atomic level. Such cycle may be repeated for forming more than one layer.

For the above described method 200, the crystalline metal oxide semiconductor film 300 including alternately deposited layers 302A-302C of the first metal oxide material and layers 304A-304C of the second metal oxide material. In some embodiments, the first metal element contained in the first metal oxide material is different from the second metal element or the third metal element contained in the second metal oxide material, either of the first, second or third metal element may independently be selected from indium, gallium, zinc, tungsten, arsenic, silicon, germanium, magnesium, gadolinium, or a combination thereof. In certain embodiments, the crystalline metal oxide semiconductor film 300 comprises indium gallium zinc oxide (IGZO), gallium arsenide (GaAs), gallium nitrogen (GaN), gallium aluminum nitride (GaAlN), indium gallium arsenide (InGaAs), indium phosphide (InP), gallium phosphide (GaP), aluminum arsenide (AlAs), aluminum gallium arsenide (AlGaAs), gallium indium phosphide (GaInP), aluminum indium gallium phosphide (AlInGaP), indium gallium zinc tungsten oxide (InGaZnWO), silicon germanium (SiGe), zinc oxide (ZnO), magnesium oxide (MgO) or gadolinium oxide (GdO), cadmium sulfide (CdS), cadmium selenide (CdSe), cadmium telluride (CdTe), zinc sulfide (ZnS), zinc selenide (ZnSe), zinc telluride (ZnTe), lead sulfide (PbS), lead telluride (PbTe). In some embodiments, the crystalline metal oxide semiconductor film 300 has a thickness of 0.1 nm to 300 nm.

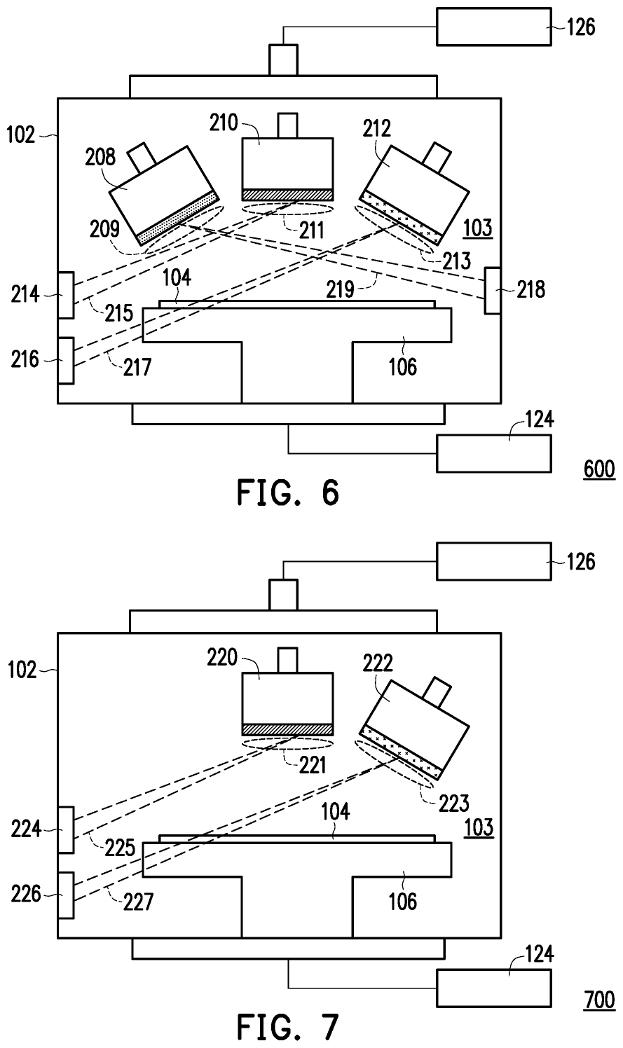

FIG. 6 is a schematic view of a thin-film deposition system 600 in accordance with some embodiments of the disclosure. In this embodiment, the method 200 as shown in FIG. 2 may be carried out in the thin-film deposition system 600 as shown in FIG. 6 to form the crystalline metal oxide semiconductor film 300 as shown in FIG. 3.

The thin-film deposition system 600 includes a deposition chamber 102 including an inner space 103. A support 106 is positioned within the inner space 103 and is configured to support a substrate 104 during a thin-film deposition process. The thin-film deposition system 600 is configured to deposit a thin film on the substrate 104. The thin-film deposition system 600 may further include a control system 124 that dynamically adjusts thin-film deposition parameters. Details of the control system 124 may refer to the description with respect to the operation of the thin-film deposition system 100 and will not be repeated redundantly.

In some embodiments, the thin-film deposition system 600 is a pulsed laser deposition (PLD) system that performs PLD processes. The PLD processes are performed in a high vacuum environment. Through the PLD processes, the crystalline metal oxide semiconductor film 300 is formed on the substrate 104, as shown in FIG. 3.

In one embodiment, the thin-film deposition system 600 includes a first target 208, a second target 210 and a third target 212 positioned in the inner space 103 of the deposition chamber 102. For example, the first target 208 is an indium oxide target, the second target 210 is a gallium oxide target, and the third target 212 is a zinc oxide target. The thin-film deposition system 600 further includes three laser sources 214, 216 and 218 configured to emit laser beams 215, 217 and 219 respectively inside the deposition chamber 102. The laser beams 215, 217 and 219 may focus on the second target 210, the third target 212 and the first target 208 respectively inside the deposition chamber 102 to vaporize the target materials of the first target 208, the second target 210 and the third target 212 (for example, indium oxide, gallium oxide and zinc oxide) in the form of a plasma plume, which subsequently deposits on the substrate as a thin film. The thin-film deposition system 600 further includes three shutters 209, 211 and 213 that can block the target materials of the first target 208, the second target 210 and the third target 212 respectively from being vaporized.

Referring to FIG. 2 again, in some embodiments, using the PLD process as an example, Process 210 of the method 200 includes providing a substrate 104 into the deposition chamber 102. Followed by performing Process 220, using the PLD process as an example, the second target 210 and the third target 212 are blocked by the shutters 211 and 213 respectively, and the laser beam 219 focuses on the first target 208 for a first period of time, such as 0.3 to 10 seconds, in order to energize the target material of the first target 208 and form a layer 302A of a first metal oxide material, such as an indium oxide, over the substrate 104 (FIG. 3).

In some embodiment, after Process 220, a purge gas may be fed into the inner space 103 during a second period of time. The purge gas may include nitrogen gas (N₂) or another nonreactive gas. In one example, the second period of time is 0.5-10 seconds, though other lengths of time may be used without departing from the scope of the present disclosure. The purge gas is exhausted through the discharge pipe 120.

Next, the first target 208 is blocked by the shutters 209, and the laser beams 215 and 217 focus on the second target 210 and the third target 212 respectively for a third period of time for co-pulsing of the second target 210 and the third target 212 in order to energize the target materials of the second target 210 and the third target 212 and form a layer 304A of a second metal oxide material directly on the layer 302A of the first metal oxide material (FIG. 3) in Process 240. In one example, the third period of time is 0.3-10 seconds, though other lengths of time may be used without departing from the scope of the present disclosure.

In some embodiments, the method 200 performs purging for a fourth period of time after Process 240. In some embodiments, Processes 220-240 are performed as a cycle, and such cycle is repeated to form a layer 302B of the first metal oxide material on the layer 304A and a layer 304B of the second metal oxide material directly on the layer 302B. In some embodiments, another cycle of Processes 220-240 is repeated to form a layer 302C of the first metal oxide material on the layer 304B and a layer 304C of the second metal oxide material directly on the layer 302C. thereby forming the crystalline metal oxide semiconductor film 300. The numbers of the layers of the first metal oxide material and the second metal oxide material may vary depending on the desired thickness of the crystalline metal oxide semiconductor film 300. Next, once the desired composite structure or the desired thickness of the crystalline metal oxide semiconductor film 300 is obtained, the method 200 may be terminated (Process 260).

In some embodiments, the thin-film deposition system 600 may be further equipped with a RF generator and two parallel electrodes, one of which is configured between the RF generator and the targets, and the other is configured between the substrate 104 and the deposition chamber 102. As a result, an enhanced plasma plume is generated to facilitate the deposition of the first metal oxide material and the second metal oxide material in a plasma enhanced pulsed laser deposition (PEPLD) process. For example, during the PEPLD process, the pressure of the deposition chamber 102 ranges from 0.01 to 20 torr, the reaction temperature is below 200° C., and the power for generating plasma is below 200 watts.

In some embodiments, the thin-film deposition system 600 is a physical vapor deposition (PVD) system that performs PVD processes, such as the sputtering process, and the laser sources 214, 216 and 218 are not needed. In order to form the crystalline metal oxide semiconductor film 300 on the substrate 104 as shown in FIG. 3, the PVD processes may be performed in a gaseous environment having a pressure of between about 0.01 Pa and 5 Pa at a temperature below 300° C. For example, the gaseous environment comprises a mixture of argon gas and oxygen gas, in which the volume ratio of the argon gas to the oxygen gas ranges from 2:3 to 3:2. In some embodiments, the PVD process is a RF sputtering process using a power of between about 100 watts and about 300 watts. In some embodiments, the duty cycle of the PVD process is maintained between about 50% and 100% during the deposition.

Referring to FIG. 2, FIG. 3 and FIG. 6 simultaneously, in some embodiments, the method 200 includes providing a substrate 104 into the deposition chamber 102 (Process 210). Followed by performing Process 220, in some embodiments, using the PVD process as an example, the target material of the first target 208 is energized (ionized) for 0.3-10 seconds to form a layer 302A of a first metal oxide material, such as an indium oxide layer, over the substrate 104 while the second target 210 and the third target 212 are blocked by the shutters 211 and 213 respectively. Next, in Process 240, both the target materials of the second target 210 and the third target 212 are energized by argon plasma for 0.3-10 seconds to form a co-sputtered layer 304A of a second metal oxide material (such as a gallium zinc oxide layer) on the layer 302A, while the first target 208 is blocked by the shutters 209. In other embodiments, other length of time for Process 220 or Process 240 may be used without departing from the scope of the present disclosure. In some embodiments, Process 220 and Process 240 are performed as a cycle, and such cycle is repeated to form a layer 302B of the first metal oxide material on the layer 304A and a layer 304B of the second metal oxide material directly on the layer 302B. In some embodiments, another cycle of Processes 220 and Process 240 is repeated to form a layer 302C of the first metal oxide material on the layer 304B and a layer 304C of the second metal oxide material directly on the layer 302C, thereby forming the crystalline metal oxide semiconductor film 300. The numbers of the layers of the first metal oxide material and the second metal oxide material may vary depending on the desired thickness of the crystalline metal oxide semiconductor film 300. Once the desired composite structure or the desired thickness of the crystalline metal oxide semiconductor film 300 is obtained, the method 200 may be terminated (Process 260).

FIG. 7 is a schematic view of a thin-film deposition system 700 in accordance with some embodiments of the disclosure. In this embodiment, the method 200 as shown in FIG. 2 may be carried out in the thin-film deposition system 700 as shown in FIG. 7 to form the crystalline metal oxide semiconductor film 300 as shown in FIG. 3.

The thin-film deposition system 700 is substantially similar to the thin-film deposition system 600, except that the thin-film deposition system 700 includes two targets 220, 222, two shutters 221, 223 and two laser sources 224, 226. For example, the target 220 is an indium oxide target, and the target 222 is a gallium oxide/zinc oxide mixture target. The laser sources 224, 226 configured to emit laser beams 225 and 227 respectively inside the deposition chamber 102. The laser beam 225 and the laser beam 227 may focus on the target 220 and the target 222 respectively inside the deposition chamber 102 to vaporize the target materials of the target 220 and the target 222 (for example, indium oxide and gallium oxide/zinc oxide mixture) in the form of a plasma plume, which subsequently deposits on the substrate as a thin film. The shutters 221 and 223 block the target materials of the target 220 and the target 222 respectively from being vaporized.

In one embodiment, the method 200 includes providing a substrate 104 into the deposition chamber 102 (Process 210). Followed by performing Process 220, the target 222 is blocked by the shutters 223, and the laser beam 225 focuses on the target 220 for a first period of time, such as 0.3 to 10 seconds, in order to form a layer 302A of a first metal oxide material, such as an indium oxide layer, over the substrate 104 (FIG. 3).

After Process 220, a purge gas may be fed into the inner space 103 during a second period of time. The purge gas may include nitrogen molecules (N₂) or another nonreactive gas. In one example, the second period of time is 0.5-10 seconds, though other lengths of time may be used without departing from the scope of the present disclosure. The purge gas is exhausted through the discharge pipe 120.

Next, the target 220 is blocked by the shutters 221, and the laser beams 227 focuses on the target 222 in order to form a layer 304A of a second metal oxide material (such as a gallium zinc oxide layer) on the layer 304A of the first metal oxide material (FIG. 3) in Process 240. In one example, the third period of time is 0.3-10 seconds, though other lengths of time may be used without departing from the scope of the present disclosure.

In some embodiments, the method 200 performs purging for a fourth period of time after Process 240. In some embodiments, Processes 220-240 are performed as a cycle, and such cycle is repeated to form a layer 302B of the first metal oxide material on the layer 304A and a layer 304B of the second metal oxide material directly on the layer 302B. In some embodiments, another cycle of Processes 220-240 is repeated to form a layer 302C of the first metal oxide material on the layer 304B and a layer 304C of the second metal oxide material directly on the layer 302C, thereby forming the crystalline metal oxide semiconductor film 300. The numbers of the layers of the first metal oxide material and the second metal oxide material may vary depending on the desired thickness of the crystalline metal oxide semiconductor film 300. Next, once the desired composite structure or the desired thickness of the crystalline metal oxide semiconductor film 300 is obtained, the method 200 may be terminated (Process 260).

In some embodiments, the thin-film deposition system 700 is a physical vapor deposition (PVD) system that performs PVD processes, such as the sputtering process, and the laser sources 224 and 226 are not needed. In order to form the crystalline metal oxide semiconductor film 300 on the substrate 104, the PVD processes may be performed in a gaseous environment having a pressure of between about 0.01 Pa and 5 Pa at a temperature below 300° C. For example, the gaseous environment comprises a mixture of argon gas and oxygen gas, in which the volume ratio of the argon gas to the oxygen gas ranges from 2:3 to 3:2. In some embodiments. the PVD process is a RF sputtering process using a power of between about 100 watts and about 300 watts. In some embodiments, the duty cycle of the PVD process is maintained between about 50% and 100% during the deposition.

Referring to FIG. 2, FIG. 3 and FIG. 7 simultaneously, in some embodiments, the method 200 includes providing a substrate 104 into the deposition chamber 102 (Process 210). Followed by performing Process 220, the target material (e.g., indium oxide) of the target 220 is energized (ionized) for 0.3-10 seconds to form a layer 302A of a first metal oxide material over the substrate 104 while the target 222 is blocked by the shutter 223. Next, in Process 240, the target 220 is blocked by the shutters 221, and the target material (e.g., gallium oxide/zinc oxide mixture) of the target 222 is energized (ionized) for 0.3-10 seconds in order to form a layer 304A of a second metal oxide material (such as a gallium zinc oxide layer) on the layer 302A. In other embodiments, other length of time for Process 220 or Process 240 may be used without departing from the scope of the present disclosure. In some embodiments, Process 220 and Process 240 are performed as a cycle, and such cycle is repeated to form a layer 302B of the first metal oxide material on the layer 304A and a layer 304B of the second metal oxide material directly on the layer 302B. In some embodiments, another cycle of Processes 220 and Process 240 is repeated to form a layer 302C of the first metal oxide material on the layer 304B and a layer 304C of the second metal oxide material directly on the layer 302C, thereby forming the crystalline metal oxide semiconductor film 300. The numbers of the layers of the first metal oxide material and the second metal oxide material may vary depending on the desired thickness of the crystalline metal oxide semiconductor film 300. Once the desired composite structure or the desired thickness of the crystalline metal oxide semiconductor film 300 is obtained, the method 200 may be terminated (Process 260).

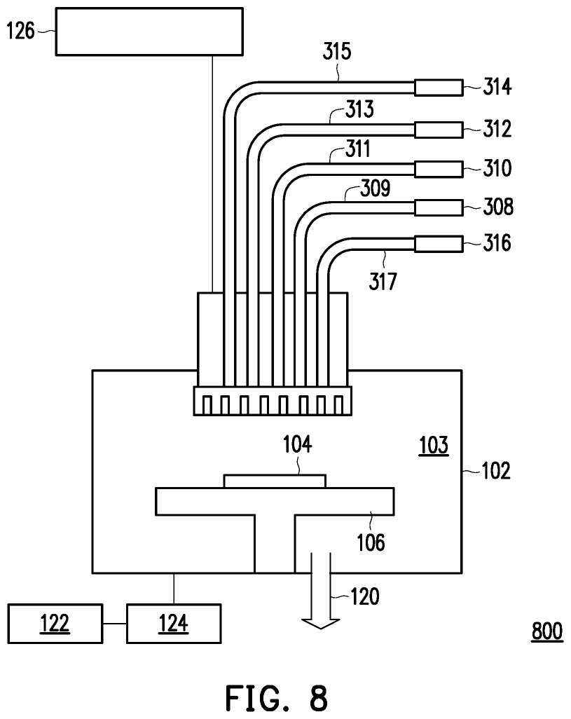

FIG. 8 is a schematic view of a thin-film deposition system 800 in accordance with some embodiments of the disclosure. In this embodiment, the method 200 as shown in FIG. 2 may be carried out in the thin-film deposition system 800 as shown in FIG. 8 to form the crystalline metal oxide semiconductor film 300 as shown in FIG. 3.

The thin-film deposition system 800 includes a deposition chamber 102 including an inner space 103. A support 106 is positioned within the inner space 103 and is configured to support a substrate 104 during a thin-film deposition process. The thin-film deposition system 800 is configured to deposit a thin film on the substrate 104.

In one embodiment, the thin-film deposition system 800 includes a discharge pipe 120 communicatively coupled to the inner space 103 of the deposition chamber 102. Exhaust products from the thin-film deposition process flow out of the inner space 103 via the discharge pipe 120. The exhaust products include unreacted portions of the first and second reactants, byproducts of the first and second reactants, carrier fluids used to carry the first and second reactants or purge the inner space 103, or other fluids or materials.

In one embodiment, the thin-film deposition system 800 may further include a control system 124 coupled to the byproduct sensor 122. The control system 124 receives the sensor signals from the byproduct sensor 122. The sensor signals from the byproduct sensor 122 are indicative of the concentration of byproducts of one or both of the first and second reactants in the exhaust fluid. In addition, the control system 124 may dynamically adjust thin-film deposition parameters. Details of the control system 124 may refer to the description with respect to the operation of the thin-film deposition system 100 and will not be repeated redundantly.

In some embodiments, the thin-film deposition system 800 is a chemical vapor deposition (CVD) system that performs CVD processes. Through the CVD processes, the crystalline metal oxide semiconductor film 300 is formed on the substrate 104, as shown in FIG. 3.

In some embodiments, the thin-film deposition system 800 includes a first reactant source 308, a second reactant source 310, a third reactant source 312 and a fourth reactant source 314. In practice, the thin-film deposition system 800 includes other numbers of reactant sources. The first reactant source 308 supplies a first reactant into the inner space 103 and is coupled to the deposition chamber 102 by a feeding line 309. The second reactant source 310 supplies a second reactant into the inner space 103 and is coupled to the deposition chamber 102 by a feeding line 311. The third reactant source 312 supplies a third reactant into the inner space 103 and is coupled to the deposition chamber 102 by a feeding line 313. The fourth reactant source 314 supplies a fourth reactant into the inner space 103 and is coupled to the deposition chamber 102 by a feeding line 315. In some embodiments, the thin-film deposition system 800 further includes a purge tank 316 supplying a carrier fluid. The purge tank 316 is coupled with the deposition chamber 102 through a purge line 317.

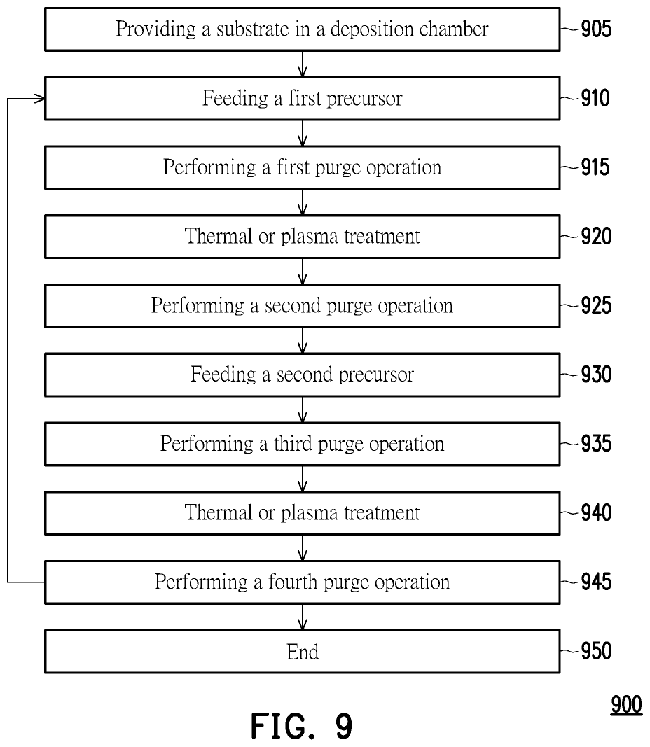

FIG. 9 is a flow diagram of a method 900 for forming a crystalline metal oxide semiconductor film in accordance with some embodiments of the disclosure. In this embodiment, using the CVD process as an example, the method 900 may be carried out in the thin-film deposition system 800 as shown in FIG. 8 to form the crystalline metal oxide semiconductor film 300 (such as a crystalline IGZO film) as shown in FIG. 3.

Referring to FIG. 3, FIG. 8 and FIG. 9 simultaneously, the method 900 starts in Process 905 in which a substrate 104 is provided in the deposition chamber 102. In some embodiments, the substrate 104 is or includes a wafer, such as a semiconductor bulk wafer or a reconstructed wafer. Followed by performing Process 910, through feeding or supplying a first precursor including first metal elements (such as indium) into the inner space 103 of the deposition chamber 102, a layer 302A of a first metal oxide material (such as an indium oxide layer) is formed over the substrate 104. In some embodiments, the first precursor comprises the first metal element and oxygen. In some embodiments, a first purge operation is performed for approximately 0.5 to 10 seconds in Process 915 following Process 910. Next, in Process 920, a thermal treatment or a plasma treatment is performed. In some embodiments, a second purge operation is performed for approximately 0.5 to 10 seconds in Process 925 following Process 920. Followed by performing Process 930, through feeding or supplying a second precursor including a second metal element (such as gallium) and a third metal element (such as zinc) into the inner space 103 of the deposition chamber 102, a layer 304A of a second metal oxide material (such as a gallium zinc oxide layer) is formed on the layer 302A of the first metal oxide material. In some embodiments, the second precursor comprises the second metal element, the third metal element and oxygen. In some embodiments, a third purge operation is performed for approximately 0.5 to 10 seconds in Process 935 after Process 930. Next, in Process 940, a thermal treatment or a plasma treatment is performed. In some embodiments, a fourth purge operation is performed for approximately 0.5 to 10 seconds in Process 945 following Process 940. In some embodiments, Processes 910-945 are performed as a cycle, and such cycle may be repeated one or more times to form multiple layers of the first metal oxide material and multiple layers of the second metal oxide material that are stacked alternately. In some embodiments, following the formation of the layers 302A, 304A, Processes 910-925 are repeated to form a layer 302B of the first metal oxide material on the layer 304A, and Processes 930-945 are repeated to form a layer 304B of the second metal oxide material directly on the layer 302B. Similarly, another cycle of Processes 910-945 may be repeated to form a layer 302C of the first metal oxide material on the layer 304B and a layer 304C of the second metal oxide material directly on the layer 302C, thereby forming the crystalline metal oxide semiconductor film 300. The numbers of the cycles and the layers of the first metal oxide material and the second metal oxide material may vary depending on the desired thickness of the crystalline metal oxide semiconductor film 300. Next, once the desired composite structure or the desired thickness of the crystalline metal oxide semiconductor film 300 is obtained, the method 900 may be terminated (Process 950).

In some embodiments, referring to FIG. 8 and FIG. 9 simultaneously, a first precursor (such as an indium precursor) is fed from, for example, the first reactant source 308 into the inner space 103 of the deposition chamber 102 through the feeding line 309 for 0.3 to 10 seconds in step 910. During the CVD process of the layer 302A of the first metal oxide material, the pressure in the deposition chamber 102 is less than 2 torr, such as 0.1 to 1.9 torr, and the reaction temperature is below 350° C. In some embodiments, a carrier fluid (such as, air, nitrogen, argon, helium or neon) is supplied from purge tank 316 and flows into the deposition chamber 102 through the purge line 317, while the first precursor is supplied into the deposition chamber 102. For example, the first precursor is indium (III) acetate (C₆H₉InO₆), indium (III) acetate hydrate (C₆H₉InO₆·xH₂O), indium (III) acetylacetonate (In(OCCH₃CHOCCH₃)₃, C₁₅H₂₁InO₆) or a combination thereof.

In some embodiments, the carrier fluid is supplied into the inner space 103 of the deposition chamber 102 and exhausted via the discharge pipe 120 during the first purge operation in Process 915, the second purge operation in Process 925, and the third purge operation in Process 935 and the fourth purge operation in Process 945. In some embodiments, the thermal treatment or plasma treatment is performed for 1 to 30 seconds in Process 920 or Process 940. The thermal treatment and plasma treatment may ensure the cleanliness of the deposition chamber 102. In some embodiments, the temperature of the thermal treatment ranges from 300° C. to 500° C. In some embodiments, the power of the plasma treatment ranges from 300 watts to 500 watts.

In some embodiments, a first component (such as a gallium precursor) and a second component (such as a zinc precursor) of the second precursor are fed from the second reactant source 310 and the third reactant source 312 into the inner space 103 of the deposition chamber 102 through the feeding line 311 and the feeding line 313 respectively for about 0.3 to 10 seconds to form the layer 304A of the second metal oxide material in step 930. During the CVD process of the second metal oxide material, the pressure in the deposition chamber 102 is less than 2 torr, such as 0.1 to 1.9 torr, and the reaction temperature is below 350° C. In some embodiments, a carrier gas, such as air, nitrogen, argon, helium or neon, is fed from purge tank 316 and flows into the deposition chamber 102 through the purge line 317 while the first component and the second component of the second precursor are flowing into the deposition chamber 102. The first component of the second precursor may be triethylgallium ((CH₃CH₂)₃Ga), trimethylgallium ((CH₃)₃Ga), tris(dimethylamido)gallium (III) (C₁₂H₃₆Ga₂N₆), gallium (III) acetylacetonate ([CH₃COCH═C(O—)CH₃]₃Ga) or a combination thereof. The second component of the second precursor may be bis(pentafluorophenyl)zinc ((C₆F₅)₂Zn), bis(2,2,6,6-tetramethyl-3,5-heptanedionato)zinc(II) (Zn(OCC(CH₃)₃CHCOC(CH₃)₃)₂), diethylzinc ((C₂H₅)₂Zn), diphenylzinc ((C₆H₅)₂Zn), zinc acetylacetonate hydrate (Zn(C₅H₇O₂)₂·xH₂O), zinc shot or a combination thereof.

In some embodiments, the first component and the second component of the second precursor are mixed to form a mixing precursor (such as a gallium/zinc precursor), which is then fed together from, for example, the second reactant source 310 into the inner space 103 of the deposition chamber 102 through the feeding line 311 in Process 930. In such circumstances, the third reactant source 312 and the feeding line 313 are not necessary.

In some embodiments, the thin-film deposition system 800 further includes a RF generator 126 for generating plasma, and the layers 302A, 302B, 302C of the first metal oxide material and the layers 304A, 304B, 304C of the second metal oxide material are deposited in a plasma enhanced chemical vapor deposition (PECVD) process. For example, during the generation of plasma, an oxygen-containing gas, such as O₂, O₃ or H₂O is fed, from, for example, the fourth reactant source 314 into the inner space 103 of the deposition chamber 102 through the feeding line 315. In some embodiments, during the PECVD process, the pressure in the deposition chamber 102 is less than 2 torr, such as 0.1 to 1.9 torr, the reaction temperature is below 300° C. the power for generating plasma is below 300 watts, and the RF frequency is about 13.56 Hz.

FIG. 10 is a schematic cross-sectional view of an exemplary structure of a top-gate thin film transistor (TFT) 10 in accordance with some embodiments of the disclosure. The top-gate TFT 10 may include a substrate SB, a semiconductor layer CH, a source terminal SE, a drain terminal DE, a gate electrode GE and a gate dielectric layer GI. The semiconductor layer CH is disposed on the substrate SB. In particular, the semiconductor layer CH is the crystalline metal oxide semiconductor film 300 including alternate stacks of the first metal oxide layer 302 and the second metal oxide layer 304. The source terminal SE is electrically connected to one end of the semiconductor layer CH, and the drain terminal DE is electrically connected to the other end of the semiconductor layer CH. The gate electrode GE is disposed above the semiconductor layer CH, and the gate dielectric layer GI is disposed between the gate electrode GE and the semiconductor layer CH. The source terminal SE and the drain terminal DE are disposed between the semiconductor layer CH and the gate dielectric layer GI. For example, the gate dielectric layer GI is also disposed between the gate electrode GE, the source terminal SE and the drain terminal DE. In some embodiments, the gate dielectric layer GI is composed of silicon oxide (SiOx) or a material with high dielectric constant (i.e., a high k material). Due to the crystalline properties of the crystalline metal oxide semiconductor film 300, the top-gate TFT 10 offers an improved channel mobility of more than 10 cm²/V−s and a reduced off state current of about 1×10⁻²⁴ A/μm, and is suitably applicable for low power consumption applications, such as artificial intelligence (AI) devices.

In one embodiment, the formation of the top-gate TFT 10 involves providing the substrate SB, and then forming the semiconductor layer CH over the substrate SB. In some embodiments, the formation of the semiconductor layer CH includes forming a crystalline metal oxide semiconductor layer similar to the crystalline metal oxide semiconductor film 300, and the manufacturing processes may be referred to the previous embodiments regarding the formation of the crystalline metal oxide semiconductor film 300, and details will not be repeated again. Following the formation of the semiconductor layer CH, a source terminal SE and a drain terminal DE are formed on the semiconductor layer CH. In some embodiments, the source terminal SE and the drain terminal DE are in direct contact with the semiconductor layer CH. Afterwards, a dielectric layer, such as a gate dielectric layer GI, is formed over the substrate SB. In some embodiments, a dielectric material layer is formed over the source and drain terminals SE, DE and the semiconductor layer CH, and then patterned through photolithographic and etching processes to form the gate dielectric layer GI. Later, a gate electrode GE is formed on the gate dielectric layer GI. In some embodiments, a metallic material layer is formed over the gate dielectric layer GI and over the source and drain terminals SE, DE and the semiconductor layer CH, and then patterned through photolithographic and etching processes to form the gate electrode GE. In some embodiments, the patterns of the gate dielectric layer GI and the gate electrode GE may be different.

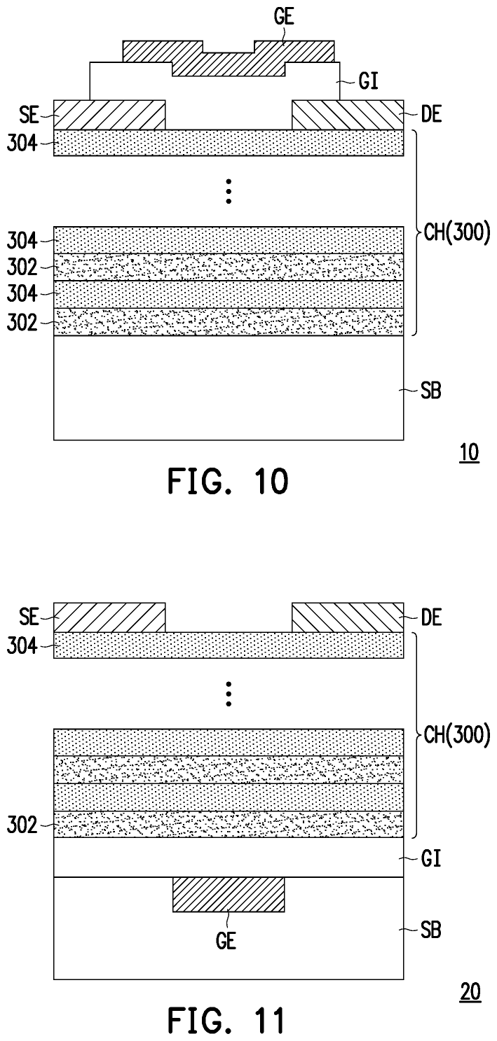

FIG. 11 is a schematic cross-sectional view of an exemplary structure of a bottom-gate TFT 20 in accordance with some embodiments of the disclosure. The bottom-gate TFT 20 may include a substrate SB, a semiconductor layer CH, a source terminal SE, a drain terminal DE, a gate electrode GE and a gate dielectric layer GI. The semiconductor layer CH is disposed above the substrate SB. In particular, the semiconductor layer CH is the crystalline metal oxide semiconductor film 300 including alternate stacks of the first metal oxide layer 302 and the second metal oxide layer 304. The gate dielectric layer GI is disposed between the substrate SB and the semiconductor layer CH. The gate electrode GE is disposed between the substrate SB and the gate dielectric layer GI. The source terminal SE and the drain terminal DE are electrically connected to both ends of the semiconductor layer CH respectively. In some embodiments, the source terminal SE and the drain terminal DE are disposed on the semiconductor layer CH.

In one embodiment, the formation of the bottom-gate TFT 20 involves providing a substrate SB having a gate electrode GE formed therein. In one embodiment, the gate electrode GE is embedded in the substrate SB. In one embodiment, the gate electrode GE is formed on the substrate SB. Next, a gate dielectric layer GI is formed on the substrate SB covering the gate electrode GE. Later, a semiconductor layer CH is formed on the gate dielectric layer GI. In some embodiments, the formation of the semiconductor layer CH includes forming a crystalline metal oxide semiconductor layer similar to the crystalline metal oxide semiconductor film 300, and the manufacturing processes may be referred to the previous embodiments regarding the formation of the crystalline metal oxide semiconductor film 300, and details will not be repeated again. Following the formation of the semiconductor layer CH, a source terminal SE and a drain terminal DE are formed on the semiconductor layer CH. In some embodiments, the source terminal SE and the drain terminal DE are formed directly on and in contact with the semiconductor layer CH.

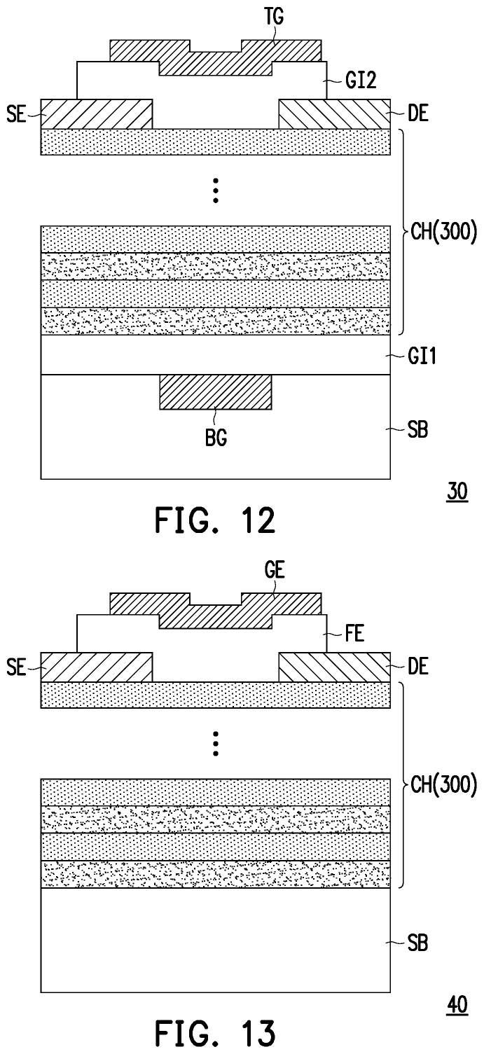

FIG. 12 is a schematic cross-sectional view of an exemplary structure of a double gate TFT 30 in accordance with some embodiments of the disclosure. The double gate TFT 30 may include a substrate SB, a top gate electrode TG, a bottom gate electrode BG, a semiconductor layer CH, a source terminal SE, a drain terminal DE and two gate dielectric layer GI1, GI2. The semiconductor layer CH is disposed above the substrate SB. In particular, the semiconductor layer CH is the crystalline metal oxide semiconductor film 300 including alternate stacks of the first metal oxide layer 302 and the second metal oxide layer 304. The gate dielectric layer GI1 is disposed between the substrate SB and the semiconductor layer CH. The bottom gate electrode BG is disposed between the substrate SB and the gate dielectric layer GI1. The top gate electrode TG is disposed above the semiconductor layer CH, and the gate dielectric layer GI2 is disposed between the top gate electrode TG and the semiconductor layer CH. The source terminal SE and the drain terminal DE are electrically connected to both ends of the semiconductor layer CH respectively. In some embodiments, the source terminal SE and the drain terminal DE are disposed between the semiconductor layer CH and the gate dielectric layer GI2. For example, the gate dielectric layer GI2 is disposed between the top gate electrode TG, the source terminal SE, the drain terminal DE and the semiconductor layer CH.

FIG. 13 is a schematic cross-sectional view of an exemplary structure of a top-gate ferroelectric field effect transistor (FeFET) 40 in accordance with some embodiments of the disclosure. The structure of the top-gate FeFET 40 is substantially similar to that of the top-gate TFT 10 as shown in FIG. 10, except that the gate dielectric layer GI of the top-gate TFT 10 is replaced with a ferroelectric layer FE. In some embodiments, the ferroelectric layer FE comprises HfₓZr₍₁₋ₓ₎O.

FIG. 14 is a schematic cross-sectional view of an exemplary structure of a bottom-gate FeFET 50 in accordance with some embodiments of the disclosure. The structure of the bottom-gate FeFET 50 is substantially similar to that of the bottom- gate TFT 20 as shown in FIG. 11, except that the gate dielectric layer GI of the bottom-gate TFT 20 is replaced with a ferroelectric layer FE.

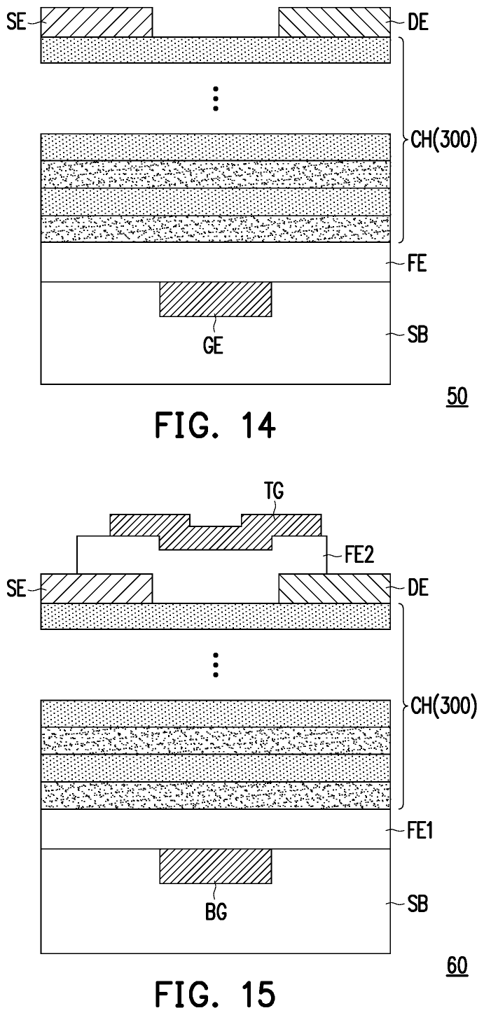

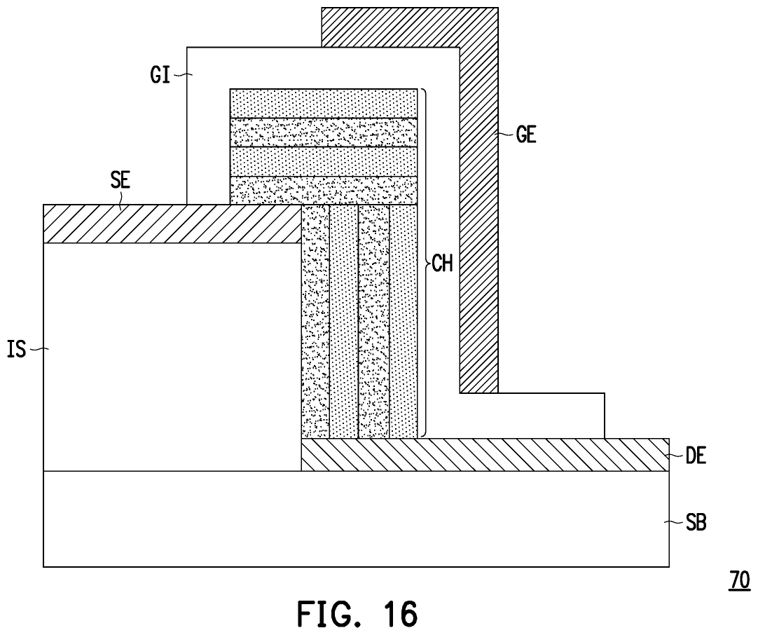

FIG. 15 is a schematic cross-sectional view of an exemplary structure of a double gate FeFET 60 in accordance with some embodiments of the disclosure. The structure of the double gate FeFET 60 is substantially similar to that of the double gate TFT 30 as shown in FIG. 12, except that the gate dielectric layers GI1, GI2 of the double gate TFT 30 are replaced with ferroelectric layers FE1, FE2 respectively.

FIG. 16 is a schematic cross-sectional view of an exemplary structure of a vertical TFT 70 in accordance with some embodiments of the disclosure. The vertical TFT 70 may include a substrate SB, a semiconductor layer CH, a source terminal SE, a drain terminal DE, a gate electrode GE, a gate dielectric layer GI and an insulating layer IS. The source terminal SE and the drain terminal DE are disposed on the substrate SB. The insulating layer IS is disposed between the source terminal SE and the substrate SB such that the spacing between the source terminal SE and the substrate SB is greater than the spacing between the drain terminal DE and the substrate SB. The semiconductor layer CH is disposed on a portion of the top surface of the source terminal SE and a portion of the top surface of the drain terminal DE. The gate dielectric layer GI covers the semiconductor layer CH completely. The gate electrode GE is disposed on a portion of the top surface of the gate dielectric layer GI and a side wall of the gate dielectric layer GI. In addition, the gate electrode GE, the source terminal SE and the drain terminal DE are electrically isolated from each other.

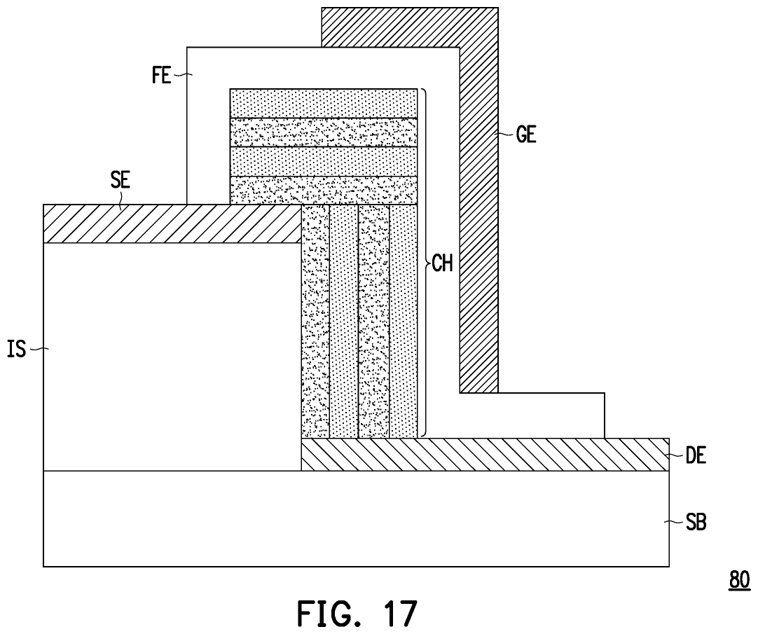

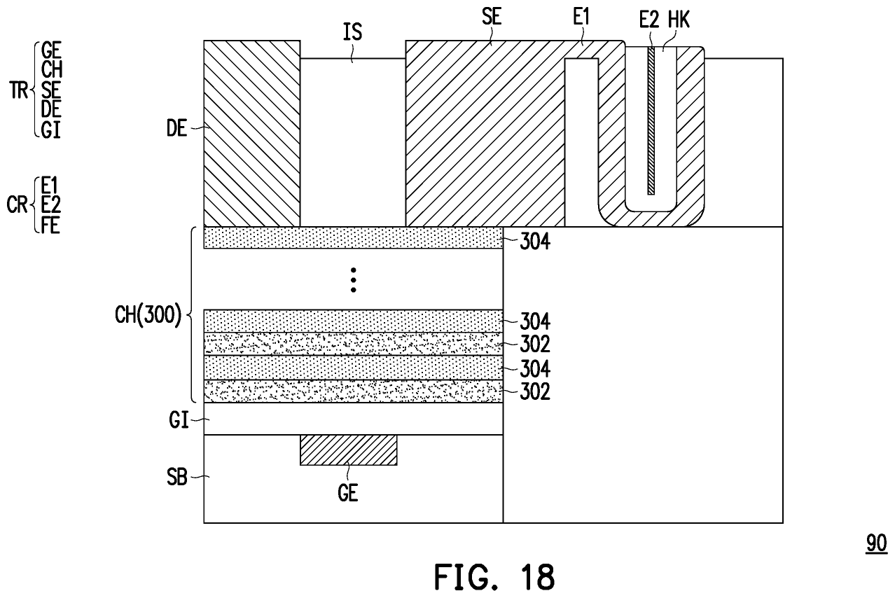

FIG. 17 is a schematic cross-sectional view of an exemplary structure of a vertical FeFET 80 in accordance with some embodiments of the disclosure. The structure of the vertical FeFET 80 is substantially similar to that of the vertical TFT 70 as shown in FIG. 13, except that the gate dielectric layer GI of the 3D or vertical TFT 70 is replaced with a ferroelectric layer FE.

FIG. 18 is a schematic cross-sectional view of a one-transistor-one-capacitor (1T1C) ferroelectric random access memory (FeRAM) cell 90 in accordance with some embodiments of the disclosure. The 1TIC FeRAM cell 90 may include a transistor TR and a capacitor device CR. In some embodiments, the transistor TR is a bottom-gate TFT. For example, the transistor TR includes a semiconductor layer CH, a source terminal SE, a drain terminal DE, a gate electrode GE and a gate dielectric layer GI. The semiconductor layer CH is disposed above the substrate SB. In particular, the semiconductor layer CH is the crystalline metal oxide semiconductor film 300 including alternate stacks of the first metal oxide layer 302 and the second metal oxide layer 304. The gate dielectric layer GI is disposed between the substrate SB and the semiconductor layer CH. The gate electrode GE is disposed between the substrate SB and the gate dielectric layer GI. The source terminal SE and the drain terminal DE are disposed on the semiconductor layer CH and electrically connected to both ends of the semiconductor layer CH respectively. In some embodiments, the 1TIC FeRAM cell 90 further comprises an insulating layer IS, which separates the source terminal SE from the drain terminal DE.

The capacitor device CR may be disposed at one side of the source terminal SE. The capacitor device CR includes a first electrode E1, a second electrode E2 and a high-k dielectric layer HK. The high-k dielectric layer HK is disposed between the first electrode E1 and the second electrode E2. For example, the high-k dielectric layer HK surrounds the second electrode E2, and the first electrode El surrounds the high-k dielectric layer HK. Further, the first electrode E1 is electrically connected to the source terminal SE. In some embodiments, the high-k dielectric layer HK comprises silicon dioxide (SiO₂) or HfₓZr₍₁₋ₓ₎O. In some embodiments, the source terminal SE and the drain terminal DE are disposed on the semiconductor layer CH, and the source terminal SE, the drain terminal DE and the ferroelectric layer FE are separated by the insulating layer IS. The conductive layer CL may surround the ferroelectric layer FE and is electrically connected to the source terminal SE.

In some embodiments of the present disclosure, a method for forming a semiconductor device is described. The method includes providing a substrate; supplying a first precursor including a first metal element; forming a first layer of a first metal oxide material containing the first metal element over the substrate, wherein the first metal element includes a Group 13 element; supplying a second precursor including a second metal element and a third metal element; forming a second layer of a second metal oxide material that contains the second metal element and the third metal element directly on the first layer to form a crystalline metal oxide semiconductor film containing the first, second and third metal elements, wherein the second metal element and the third metal element are different and each being independently selected from Group 12 elements, Group 13 elements, and Group 15 elements, and the second and third metal elements contained in the second metal oxide material are aligned with the first metal element contained in the first metal oxide material along a vertical crystalline axis direction to form the crystalline metal oxide semiconductor film; forming a source terminal and a drain terminal respectively on and in contact with the crystalline metal oxide semiconductor film; forming a dielectric layer over the substrate; and forming a gate layer on the dielectric layer.

In some embodiments, supplying a first precursor including a first metal element comprises providing first metal particles and supplying an oxygen-containing gas. In some embodiments, the method further comprises performing a plasma treatment during supplying the oxygen-containing gas. In some embodiments, the first precursor includes the first metal element and oxygen. In some embodiments, the method further comprises performing a plasma treatment or a thermal treatment after supplying the first precursor. In some embodiments, supplying a second precursor including a second metal element and a third metal element comprises co-supplying second metal particles and third metal particles, and supplying an oxygen-containing gas. In some embodiments, the method further comprises performing a plasma treatment during supplying the oxygen-containing gas. In some embodiments, the second precursor includes the second metal element, the third metal element and oxygen. In some embodiments, the method further comprises performing a plasma treatment or a thermal treatment after supplying the second precursor. In some embodiments, the first metal oxide material includes indium oxide, the second metal oxide material includes gallium zinc oxide, and the crystalline metal oxide semiconductor film includes c-axis aligned crystalline indium gallium zinc oxide.

In some embodiments of the present disclosure, a method for forming a semiconductor device is described. The method includes: providing a deposition chamber equipped with a first target including a first metal oxide material and a second target including a second metal oxide material, wherein the first metal oxide material contains a first metal element including a Group 13 element, and the second metal oxide material contains a second metal element and a third metal element, each independently selected from Group 12 elements, Group 13 elements, and Group 15 elements; providing a substrate in the deposition chamber; forming a first layer of the first metal oxide material over the substrate by ejecting the first metal oxide material from the first target to the substrate; forming a second layer of the second metal oxide material directly on the first layer by ejecting the second metal oxide material from the second target to the first layer over the substrate, wherein the second metal element and the third metal element are different elements, and the second and third metal elements contained in the second layer are aligned with the first metal element contained in the first layer along a vertical crystalline axis direction to form a crystalline metal oxide semiconductor film; forming a source terminal and a drain terminal respectively on the crystalline metal oxide semiconductor film and in contact with the crystalline metal oxide semiconductor film; forming a dielectric layer over the substrate; and forming a gate layer on the dielectric layer.

In some embodiments, the first target and the second target are alternately energized. In some embodiments, the first target and the second target are energized by laser pulses. In some embodiments, the first target and the second target are energized by argon plasma in a gaseous environment comprising a mixture of argon gas and oxygen gas, and a volume ratio of the argon gas to the oxygen gas ranges from 2:3 to 3:2. In some embodiments, the first metal oxide material is indium oxide, and the second metal oxide material is gallium zinc oxide.

In some embodiments of the present disclosure, a method for forming a semiconductor device is described. The method includes: providing a substrate; forming a first layer of indium oxide layer over the substrate; forming a second layer of gallium zinc oxide directly on the first layer to form a crystalline indium gallium zinc oxide film over the substrate; forming a source terminal and a drain terminal respectively on and in contact with the crystalline indium gallium zinc oxide film; forming a dielectric layer over the substrate; and forming a gate layer on the dielectric layer.

In some embodiments, the crystalline indium gallium zinc oxide film has a multi-layered structure including the first layer of indium oxide and the second layer of gallium zinc oxide, and gallium element and zinc element contained in the second layer are aligned with indium element contained in the first layer along a c-axis direction. In some embodiments, the dielectric layer is formed after forming the source terminal and the drain terminal, and the gate layer is formed after forming the dielectric layer. In some embodiments, the dielectric layer is formed before the crystalline indium gallium zinc oxide film is formed, and the gate layer is formed before the crystalline indium gallium zinc oxide film is formed. In some embodiments, forming the dielectric layer includes forming a ferroelectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
providing a substrate;
supplying a first precursor including a first metal element;
forming a first layer of a first metal oxide material containing the first metal element over the substrate, wherein the first metal element includes a Group 13 element;
supplying a second precursor including a second metal element and a third metal element;
forming a second layer of a second metal oxide material that contains the second metal element and the third metal element directly on the first layer to form a crystalline metal oxide semiconductor film containing the first, second and third metal elements, wherein the second metal element and the third metal element are different and each being independently selected from Group 12 elements, Group 13 elements, and Group 15 elements, and the second and third metal elements contained in the second metal oxide material are aligned with the first metal element contained in the first metal oxide material along a vertical crystalline axis direction to form the crystalline metal oxide semiconductor film;
forming a source terminal and a drain terminal respectively on and in contact with the crystalline metal oxide semiconductor film;
forming a dielectric layer over the substrate; and
forming a gate layer on the dielectric layer.

2. The method of claim 1, wherein supplying a first precursor including a first metal element comprises providing first metal particles and supplying an oxygen-containing gas.

3. The method of claim 2, further comprising performing a plasma treatment during supplying the oxygen-containing gas.

4. The method of claim 1, wherein the first precursor includes the first metal element and oxygen.

5. The method of claim 4, further comprising performing a plasma treatment or a thermal treatment after supplying the first precursor.

6. The method of claim 1, wherein supplying a second precursor including a second metal element and a third metal element comprises co-supplying second metal particles and third metal particles, and supplying an oxygen-containing gas.

7. The method of claim 6, further comprising performing a plasma treatment during supplying the oxygen-containing gas.

8. The method of claim 1, wherein the second precursor includes the second metal element, the third metal element and oxygen.

9. The method of claim 8, further comprising performing a plasma treatment or a thermal treatment after supplying the second precursor.

10. The method of claim 1, wherein the first metal oxide material includes indium oxide, the second metal oxide material includes gallium zinc oxide, and the crystalline metal oxide semiconductor film includes c-axis aligned crystalline indium gallium zinc oxide.

11. A method for forming a semiconductor device, comprising:
providing a deposition chamber equipped with a first target including a first metal oxide material and a second target including a second metal oxide material, wherein the first metal oxide material contains a first metal element including a Group 13 element, and the second metal oxide material contains a second metal element and a third metal element, each independently selected from Group 12 elements, Group 13 elements, and Group 15 elements;
providing a substrate in the deposition chamber;
forming a first layer of the first metal oxide material over the substrate by ejecting the first metal oxide material from the first target to the substrate;
forming a second layer of the second metal oxide material directly on the first layer by ejecting the second metal oxide material from the second target to the first layer over the substrate, wherein the second metal element and the third metal element are different elements, and the second and third metal elements contained in the second layer are aligned with the first metal element contained in the first layer along a vertical crystalline axis direction to form a crystalline metal oxide semiconductor film;
forming a source terminal and a drain terminal respectively on the crystalline metal oxide semiconductor film and in contact with the crystalline metal oxide semiconductor film;
forming a dielectric layer over the substrate; and
forming a gate layer on the dielectric layer.

12. The method of claim 11, wherein the first target and the second target are alternately energized.

13. The method of claim 11, wherein the first target and the second target are energized by laser pulses.

14. The method of claim 13, wherein the first target and the second target are energized by argon plasma in a gaseous environment comprising a mixture of argon gas and oxygen gas, and a volume ratio of the argon gas to the oxygen gas ranges from 2:3 to 3:2.

15. The method of claim 11, wherein the first metal oxide material is indium oxide, and the second metal oxide material is gallium zinc oxide.

16. A method for forming a semiconductor device, comprising:
providing a substrate;
forming a first layer of indium oxide layer over the substrate;
forming a second layer of gallium zinc oxide directly on the first layer to form a crystalline indium gallium zinc oxide film over the substrate;
forming a source terminal and a drain terminal respectively on and in contact with the crystalline indium gallium zinc oxide film;
forming a dielectric layer over the substrate; and
forming a gate layer on the dielectric layer.

17. The method of claim 16, wherein the crystalline indium gallium zinc oxide film has a multi-layered structure including the first layer of indium oxide and the second layer of gallium zinc oxide, and gallium element and zinc element contained in the second layer are aligned with indium element contained in the first layer along a c-axis direction.

18. The method of claim 16, wherein the dielectric layer is formed after forming the source terminal and the drain terminal, and the gate layer is formed after forming the dielectric layer.

19. The method of claim 16, wherein the dielectric layer is formed before the crystalline indium gallium zinc oxide film is formed, and the gate layer is formed before the crystalline indium gallium zinc oxide film is formed.

20. The method of claim 16, wherein forming the dielectric layer includes forming a ferroelectric layer.
